(19) United States
(12) Patent Application Publication
(10) Pub. No.: US 2013/0163155 A1
(43) Pub. Date: Jun. 27, 2013

(54) ELECTRONIC DEVICE HAVING SENSOR WINDOW COVER

(71) Applicant: BAO-GANG ZHAO, Shenzhen City (CN)

(72) Inventor: BAO-GANG ZHAO, Shenzhen City (CN)

(73) Assignees: HON HAI PRECISION INDUSTRY CO., LTD., Tu-Cheng (TW); HONG FU JIN PRECISION INDUSTRY (SHENZHEN) CO., LTD., Shenzhen City (CN)

(21) Appl. No.: 13/531,130

(22) Filed: Jun. 22, 2012

(30) Foreign Application Priority Data
Dec. 24, 2011 (CN) 201110438369.7

(51) Int. Cl. H05K 7/00

(52) U.S. Cl. 361/679.01

(57) ABSTRACT

An electronic device includes a housing having a front case, a signal receiving unit, and a cover secured to the front case and corresponding to the signal receiving unit. The cover includes a first end, a second end, and a window arranged between the first end and the second end. The front case defines a through hole for receiving the window. Two clipping members and at least one latching member are secured on the front case and are arranged at opposite sides of the through hole. The clipping members define a clipping space for receiving opposite ends of the first end of the cover. The at least one latching member elastically clip the second end of the cover and cooperate with the clipping members to steadily secure the cover to the front case.

### BACKGROUND

1. Technical Field

The present disclosure relates to electronic devices, and particularly to an electronic device having a sensor window cover.

2. Description of Related Art

Electronic devices, such as DVD players, may include a housing and a sensor window cover secured to the housing. The sensor window cover includes a hook member. The housing defines an area to be covered by the sensor window cover, and includes a latching member arranged adjacent to the area. The latching member corresponds to the hook member and hooks the hook member to secure the sensor window cover to the housing. However, if the sensor window cover is made of polymethyl methacrylate, which is very brittle, the sensor window cover may be broken when being secured to the housing.

Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the six views.

FIG. 1 is a partial perspective view of an electronic device having a sensor window cover in accordance with an embodiment.

FIG. 2 is a partially enlarged view of the electronic device of FIG. 1.

FIG. 3 is a disassembled view of the electronic device of FIG. 2.

FIG. 4 is an enlarged view of a portion of the electronic device of FIG. 3.

FIG. 5 is a perspective view of the sensor window cover in FIG. 1.

FIG. 6 is an assembly view of the electronic device of FIG. 2.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

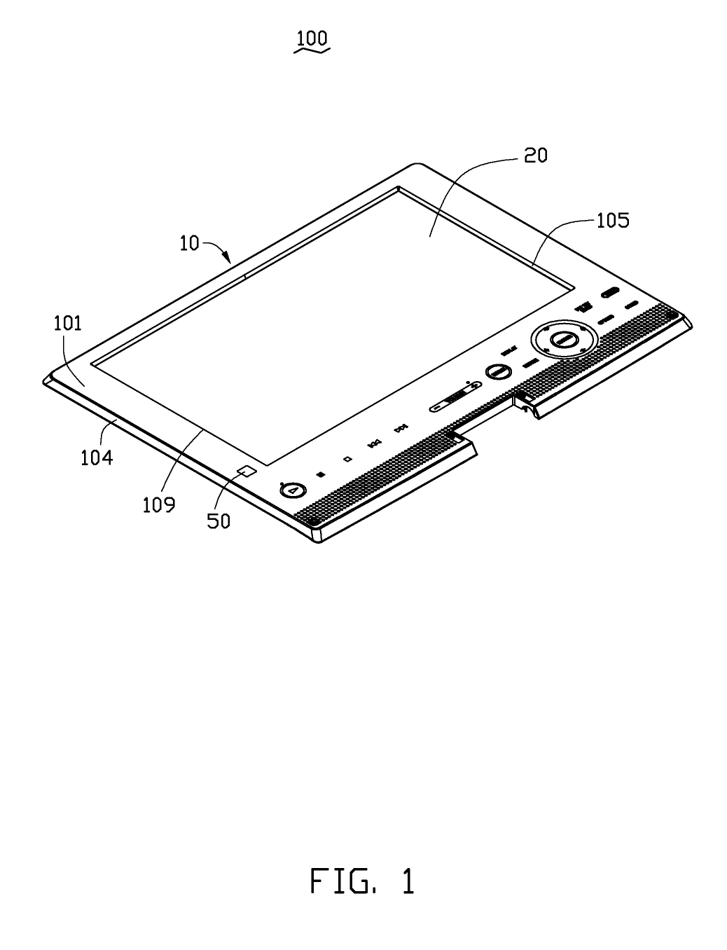

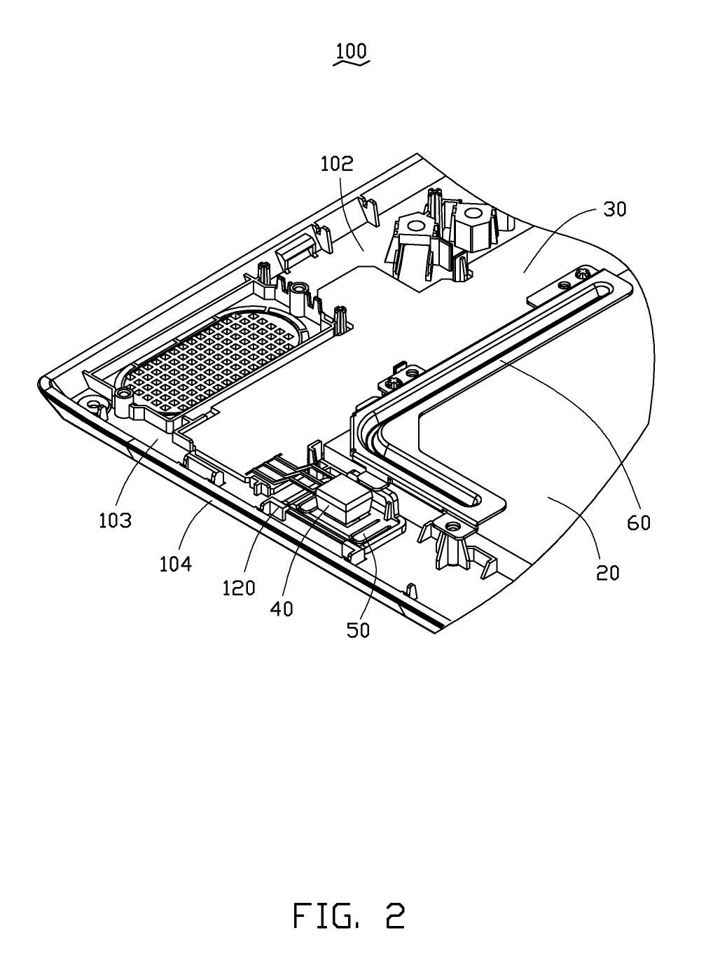

Referring to FIGS. 1-2, an electronic device 100 having a sensor window cover 50 is shown. The electronic device 100 includes a housing 10, a display 20 secured to the housing 10, a circuit board 30 received in the housing 101, a signal receiving unit 40 arranged on the circuit board 30, and a sensor window cover 50 secured to the housing 10 and corresponding to the signal receiving unit 40. The electronic device 100 further includes a plurality of fixing members 60 for fixing the display 20 to the housing 10.

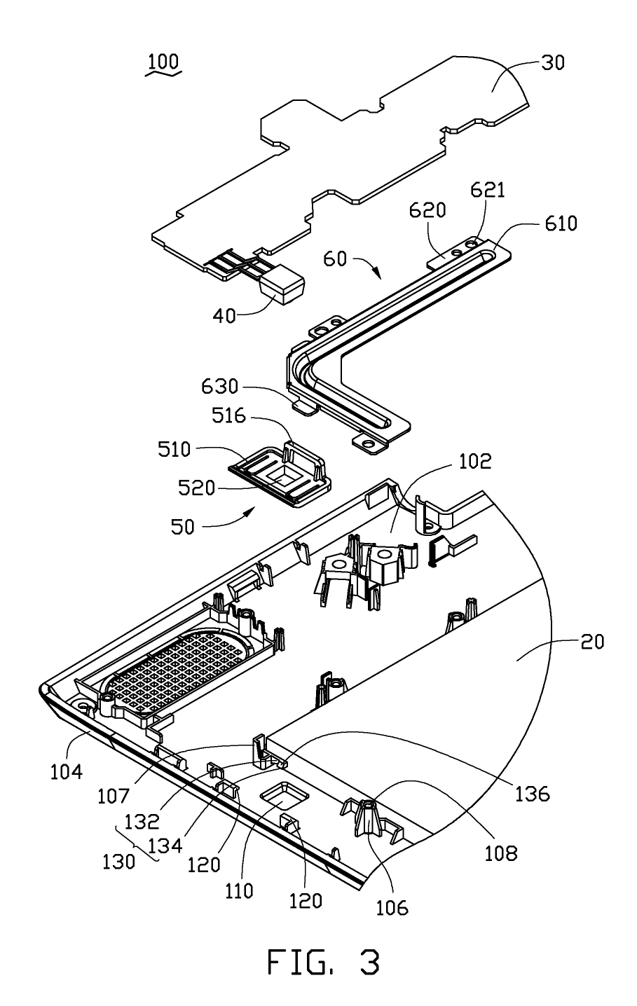

The housing 10 includes a front case 101 and a rear case (not shown). The front case 101 engages with the rear case to define a receiving space 102 for receiving the display 20, the circuit board 30, the signal receiving unit 40, and other electronic components (not shown) of the electronic device 100. The front case 101 includes a front wall 103 and a plurality of sidewalls protruding from rims of the front wall 103. A left one of the sidewalls is referred to herein as the first sidewall 104 when viewed from the front of the electronic device 100. The front wall 103 defines an opening 105. The opening 105 is substantially rectangular and smaller than the display 20. Referring to FIG. 3, the front wall 103 further defines a through hole 110. The through hole 110 is substantially rectangular, and is arranged between the first sidewall 104 and the left end 109 of the opening 105.

A plurality of fixing posts 106 and protruding posts 107 protrude from an inner surface of the front wall 103. The fixing posts 106 and the protruding posts 107 are spaced from each other, and are arranged adjacent to the left end 109. Each fixing post 106 defines a fixing hole 108 for receiving fixing components, such as screws (not shown). Two clipping members 120 are arranged on the inner surface of the front wall 103 and connect with the first sidewall 104. The through hole 110 is equidistant between the two clipping members 120.

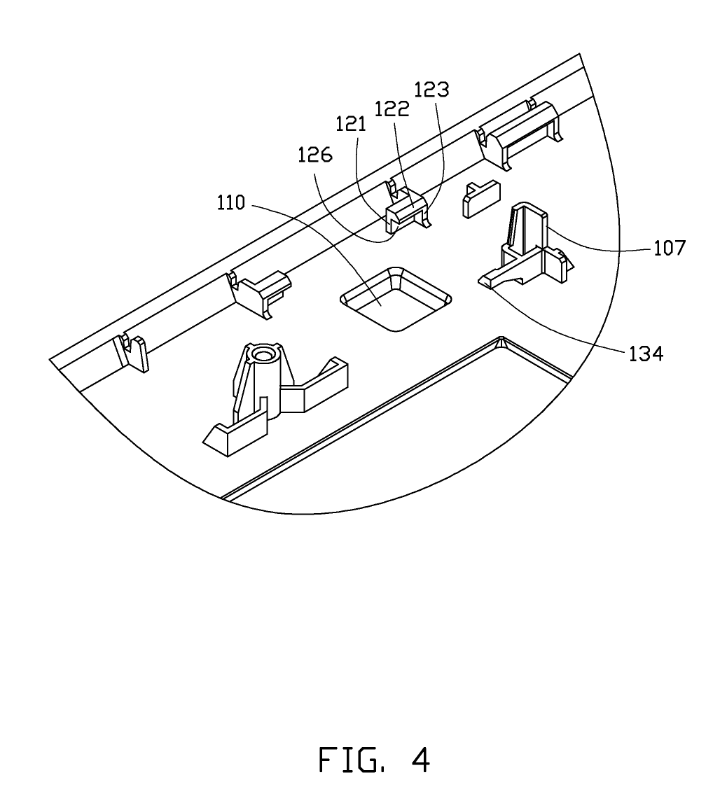

Referring to FIG. 4, each clipping member 120 includes an abutting portion 121, a hook 122, and a limiting portion 123. The abutting portion 121 perpendicularly protrudes from the inner surface of the front wall 103 and is spaced from the first sidewall 104. In the embodiment, the abutting portions 121 are aligned in a plane parallel to the first sidewall 104. The hook 122 bends from an end of the abutting portion 121 away from the front wall 103 and extends in a direction opposite to the first sidewall 104. The limiting portion 123 perpendicularly protrudes from the inner surface of the front wall 103 and is secured to an end of the abutting portion 121 away from the other clipping member 120. The abutting portion 121, the hook 122, and the front wall 103 cooperatively define a clipping space 126.

A latching member 130 is secured to the inner surface of the front wall 103. The latching member 130 is arranged adjacent to the left end 109 of the opening 105. In the embodiment, the latching member 130 is secured to the protruding post 107, the latching member 130 and one of the clipping members 120 (hereinafter, the corresponding clipping member) are aligned in a line perpendicular to the first sidewall 104. The latching member 130 includes an elastic arm 132 and a latch 134. The elastic arm 132 extends from the protruding post 107 and is spaced from the front wall 103. The latch 134 is fixed to an end of the elastic arm 132 away from the protruding post 107 and extends toward the corresponding clipping member 120. The distance between the latch 134 and the front wall 103 is substantially equal to the distance between the hooks 122 and the front wall 103. The latch 134 defines an inclined surface 136. The inclined surface 136 faces the corresponding clipping member 120. When the inclined surface 136 is pressed, the elastic arm 132 is elastically deformed to move away from the corresponding member 120. In other embodiments, the elastic arm 132 perpendicularly protrudes from the inner surface of the front wall 103 and the latch 134 is bent from an end of the elastic arm 132 away from the front wall 103 and extends toward the corresponding clipping member 120.

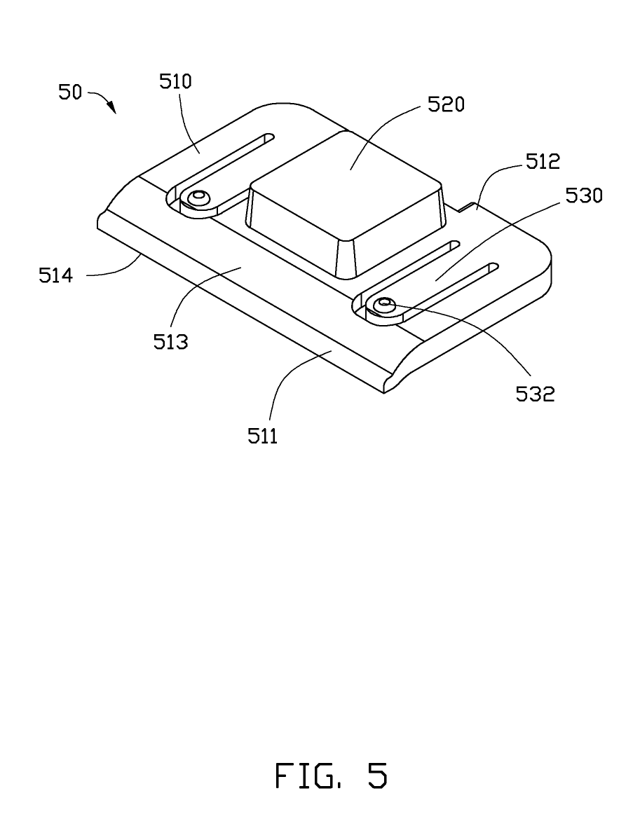

Referring to FIG. 5, the sensor window cover 50 includes a base 510 and a window 520 arranged on the base 510. The base 510 is substantially rectangular and includes a first end 511, and a second end 512 opposite to the first end 511. The length of the base 510 is slightly less than the distance between the limiting portions 123, and the width of the base 510 (namely, the distance between the first and second ends 511, 512) is slightly less than the distance between the elastic arm 132 and a plane (not labeled) in which the abutting portions 121 are aligned. In the embodiment, the thickness of the first end 511 is less than the thickness of the second end 512 and is less than the distance between the hooks 122 and the front wall 103. The thickness of the second end 512 is slightly less than the distance between the latch 134 and the front wall 103.

The window 520 is arranged at the middle of the base 510. The size of the window 520 is slightly less than the size of the through hole 110. When viewed from a front surface 513 of the base 510, the window 520 protrudes out of the front surface 513 of the base 510; when viewed from a rear surface 514 of the base 510, the window 520 is recessed in the rear surface 514 of the base 510. In the embodiment, the sensor window cover 50 is made of polymethyl methacrylate.

A resisting member 516 is secured to the rear surface 514 of the base 510. The resisting member 516 is arranged adjacent to the second end 512. Two ribs 518 protrude from the rear surface 514 and connect with opposite ends of the resisting member 516 respectively to enhance the stiffness of the resisting member 516. Two elastic cantilevers 530 are arranged at opposite sides of the window 520. Each elastic cantilever 530 is substantially U-shaped, and is integrally formed by punching the base 510 in the embodiment. A protrusion 532 protrudes from a free end of each elastic cantilever 530. The protrusions 532 extend out of the front surface 513.

Referring again to FIG. 3, the latching members 60 are used for fixing the display 20 to the housing 10. One of the fixing members 60 (referred herein as the first latching member 60) is fixed to a vertex of the opening 105 adjacent to the through hole 110 by screws (not shown) being threaded into corresponding fixing holes 108. The first latching member 60 includes an abutting plate 610, a plurality of protruding plates 620 protruding from a rim of the abutting plate 610, and a resisting plate 630 protruding from a rim of the abutting plate 610 and corresponding to the revisiting member 516. The abutting plate 610 is substantially L-shaped in the embodiment, and is used to abut the display 20. Each resisting plate 620 defines an aperture 621. The apertures 621 correspond to the fixing holes 108 for allowing screws to pass therethrough. The resisting plate 630 is bent from a rim of the abutting plate 610 adjacent to the through hole 110.

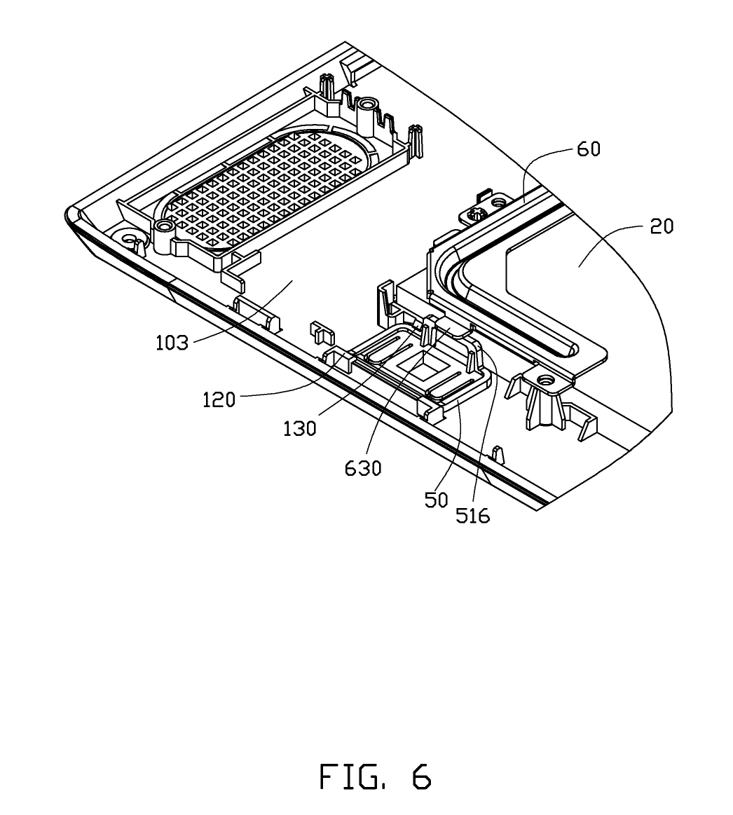

Referring to FIG. 6, in assembly, firstly, the first end 511 of the base 510 is received in the clipping spaces 216. Secondly, the second end 512 is operated to press the inclined surface 136 of the latch 134, deforming the elastic arm 132 to make room for the second end to be clipped between the latch 134 and the front wall 103, and the first and second ends 511, 512 are further clipped between the elastic arm 132 and the abutting portions 121 after the elastic arm 132 restores. At this time, the base 510 is secured to the front case 101 with the window 520 being received in the through hole 110 and the protrusions 532 abutting the inner surface of the front wall 103. Thirdly, the display 20 is secured to the front case 101 by the latching members 60, and the resisting plate 630 abuts the resisting portion 516 of the sensor window cover 50. As a result, the sensor window cover 50 is more stably secured to the housing 101 after the display 20 is secured to the housing 10 by the latching members 60. Furthermore, because the protrusions 532 of the elastic cantilevers 530 elastically abut the front wall 103, the sensor window cover 50 is prevented from loosening after the sensor window cover 50 is secured to the housing 10.

It is to be understood, even though information as to, and advantages of, the present embodiments have been set forth in the foregoing description, together with details of the structures and functions of the present embodiments, the disclosure is illustrative only; and that changes may be made in detail, especially in the matters of shape, size, and arrangement of parts within the principles of the present embodiments to the full extent indicated by the broad general meaning of the terms in which the appended claims are expressed.

What is claimed is:

1. An electronic device, comprising:
a housing having a front case;
a signal receiving unit received in the housing; and
a cover secured to the front case and corresponding to the signal receiving unit, the cover comprising a first end, a second end opposite to the first end, and a window arranged between the first end and the second end;
wherein the front case defines a through hole for receiving the window, two clipping members and at least one latching member are secured on an inner surface of the front case and are arranged at opposite sides of the through hole, the clipping members define a clipping space for receiving opposite ends of the first end of the cover; the at least one latching member is capable of elastically clipping the second end of the cover and cooperate with the clipping members to steadily secure the cover to the front case with the widow being in the through hole.

2. The electronic device of claim 1, wherein each clipping member comprises an abutting portion protruding from inner surface of the front case and a hook bent from an end of the abutting portion away from the front case, the hook and the abutting portion cooperate with the front case to define the clipping space.

3. The electronic device of claim 2, wherein the distance between the hook and the front wall is slightly greater than the thickness of the first end of the cover.

4. The electronic device of claim 2, wherein each clipping member further comprises a limiting portion secured to an end of the abutting portion away from the other one of the clipping member.

5. The electronic device of claim 4, wherein the two limiting portions are parallel to each other, and the distance between the two limiting portions is slightly greater than the length of the first end of the cover.

6. The electronic device of claim 1, wherein each the latching member comprises an elastic arm protruding from the inner surface of the front case and a latch secured to an end of the elastic arm away from the front case, the distance between the latch and the front case is slightly greater than the thickness of the second end of the cover.

7. The electronic device of claim 6, wherein the elastic arm is parallel to a plane in which the clipping members are aligned, and the distance between the elastic arm and the plane is slightly greater than the width of the cover, and the distance between the latch and the plane is less than the width of the cover.

8. The electronic device of claim 7, wherein each latch defines an inclined surface, the inclined surface faces the clipping members.

9. The electronic device of claim 1, further comprising a display and a plurality of fixing members for fixing the display to the front case.

10. The electronic device of claim 1, further comprising a display and at least one first fixing member for fixing the display to the front case.

11. The electronic device of claim 10, wherein a resisting member protrudes from a surface of the cover opposite to the window.

12. The electronic device of claim 11, wherein the at least one first fixing member abuts the resisting member when the at least one first fixing member fix the display to the front case.

13. The electronic device of claim 1, wherein at least two elastic cantilevers are arranged at the cover and are arranged at opposite sides of the window, the at least two elastic cantilevers resist the inner surface of the front case when the window is secured to the front case.

14. The electronic device of claim 13, wherein each elastic cantilever is integrally formed by punching.

15. The electronic device of claim 13, wherein a protrusion protrudes from a free end of each elastic cantilever, the protrusions extend out of the surface of the window on which the window is arranged.
